(19) United States
(12) Patent Application Publication
(10) Pub. No.: US 2021/0343615 A1
(43) Pub. Date: Nov. 4, 2021

(54) SEMICONDUCTOR PACKAGES WITH PASSIVATING MATERIAL ON DIE SIDEWALLS AND RELATED METHODS

(71) Applicant: SEMICONDUCTOR COMPONENTS INDUSTRIES, LLC, Phoenix, AZ (US)

(72) Inventors: Francis J. CARNEY, Mesa, AZ (US); Michael J. SEDDON, Gilbert, AZ (US)

(73) Assignee: SEMICONDUCTOR COMPONENTS INDUSTRIES, LLC, Phoenix, AZ (US)

(21) Appl. No.: 16/862,244

(22) Filed: Apr. 29, 2020

(51) Int. Cl. H01L 23/31; H01L 21/78; H01L 21/56

(52) U.S. Cl. CPC H01L 23/3185; H01L 23/3171; H01L 23/291; H01L 21/561; H01L 21/78

(57) ABSTRACT

Implementations of a semiconductor package may include a singulated die and a passivating material of a predetermined thickness across a majority of a singulated surface of the singulated die on at least one singulated surface of the singulated die.

### BACKGROUND

### 1. Technical Field

Aspects of this document relate generally to semiconductor packages. More specific implementations involve semiconductor packages with semiconductor die therein.

### 2. Background

Semiconductor package fabrication processes may involve many steps. In some processes a wafer receives one or more layers, such as electrically conductive layers. Electrically conductive layers may be used to provide electrical contact areas of individual semiconductor devices singulated from the wafer. Electrically conductive layers may be formed using sputtering, evaporation, or electroplating operations. Further, in some processes the overall size of the semiconductor package may designed to be minimized.

### SUMMARY

Implementations of a semiconductor package may include a singulated die and a passivating material of a predetermined thickness across a majority of a singulated surface of the singulated die on at least one singulated surface of the singulated die.

Implementations of a semiconductor package may include one, all, or any of the following:

The singulated die may include a perimeter including a closed shape.

The singulated die may include a perimeter including a rectangular shape.

The singulated die may include a perimeter including an elliptical shape.

The singulated die may include a perimeter including a triangular shape.

The singulated die may include a perimeter including a polygonal shape.

The passivating material may include one of silicon dioxide and borophosphosilicate glass (BPSG).

Implementations of a semiconductor package may include a die having a first largest planar surface and a second largest planar surface, the die including a thickness between the first largest planar surface and the second largest planar surface, the thickness including a cut surface; and a passivating material of a predetermined thickness coupled at the thickness and extending along at least half of the cut surface of the thickness to the second largest planar surface.

Implementations of a semiconductor package may include one, all, or any of the following:

The die may include a perimeter including a closed shape.

The die may include a perimeter including a rectangular shape.

The die may include a perimeter including an elliptical shape.

The die may include a perimeter including a triangular shape.

The die may include a perimeter including a polygonal shape.

The passivating material may include one of silicon dioxide and borophosphosilicate glass (BPSG).

Implementations of a method of singulating a die may include at least partially separating each of a plurality of die from each other at a plurality of junctions between each of the plurality of die, each of the plurality of die including a thickness including a cut surface; and forming a passivating material of a predetermined thickness across at least a portion of the cut surface of the thickness.

Implementations of methods of singulating a die may include one, all, or any of the following:

Forming the passivating material further may include using chemical vapor deposition.

Each of the plurality of die may be separated through one of stealth dicing, sawing, etching, laser ablating, laser damaging, scribing and breaking, or scribing and expanding.

The method may include masking to prevent growth of the passivating material on a largest planar surface of each of the plurality of die.

The masking may include forming a photoresist layer on the largest planar surface of each of the plurality of die.

The method may include overmolding each of the plurality of die with a mold compound.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 illustrates a cross-sectional side view of a semiconductor package including a mold compound applied to a first side of a wafer;

FIG. 2 illustrates a cross-sectional side view of the semiconductor package including a backside metal layer coupled to a second side of the wafer;

FIG. 3 illustrates a cross-sectional side view of the semiconductor package after the mold compound has been background;

FIG. 4 illustrates a cross-sectional side view of the wafer after singulation into plurality of die;

FIG. 5 illustrates a cross-sectional side view of a single die with oxide on the die sidewalls;

FIG. 6 illustrates a cross-sectional side view of a wafer including semiconductor die;

FIG. 7 illustrates a cross-sectional side view of the wafer including notches formed in a first side of the wafer;

FIG. 8 illustrates a cross-sectional side view of the wafer after overmolding;

FIG. 9 illustrates a cross-sectional side view of the wafer after sawing;

FIG. 10 illustrates a cross-sectional side view of a semiconductor die with oxide on the die sidewalls;

FIG. 11 illustrates a cross-sectional side view of a semiconductor die coupled to a support;

FIG. 12 illustrates an alternative cross-sectional side view of a semiconductor die coupled to a support;

FIG. 13 illustrates an alternative cross-sectional side view of a wafer including semiconductor die;

FIG. 14 illustrates a cross-sectional side view of a wafer after overmolding on the backside of the wafer;

FIG. 15 illustrates a cross-sectional side view of the wafer after sawing through to a mold compound;

FIG. 16 illustrates a cross-sectional side view of oxide formed on a die sidewalls;

FIG. 17 illustrates a cross-sectional side view of a semiconductor die coupled to a tape; and

FIG. 18 illustrates a cross-sectional side view of a semiconductor substrate with grooves with oxide deposited therein;

FIG. 19 illustrates the semiconductor substrate of FIG. 18 mounted to a dicing tape and frame prior to saw singulation;

FIG. 20 illustrates a first implementation of a semiconductor die with oxide partially extending along a singulated sidewall;

FIG. 21 illustrates a second implementation of a semiconductor die with oxide extending substantially half way along a singulated sidewall of the die; and

FIG. 22 illustrates a third implementation of a semiconductor die with oxide extending substantially three quarters of the way along a singulated sidewall of the die.

### DESCRIPTION

This disclosure, its aspects and implementations, are not limited to the specific components, assembly procedures or method elements disclosed herein. Many additional components, assembly procedures and/or method elements known in the art consistent with the intended semiconductor package will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

Referring to FIG. 1, a cross-sectional side view of a semiconductor package including a mold compound applied to a first side of a wafer is illustrated. The method of forming such a package includes forming a plurality of electrical connectors 12 on a first side 14 of a wafer 2 that includes a plurality of semiconductor die 4. In the implementation illustrated, two layers of material have been deposited over a die pad formed as part of the fabrication process for each semiconductor die. However, in other implementations, just a die pad may be used, or one or more layers of electrically conductive material may be employed. As illustrated, the method may also include forming a plurality of recesses 6 into the first side 14 of the wafer 2 to a desired depth into the wafer 2. In various implementations, the depth of each recess of the plurality of recesses 6 may be less than 50 um, while in other implementations the depth may be 50 or more micrometers depending on the thickness of the wafer. In other method implementations, however, the method may not include a recess forming step, instead, the existing depth of the die streets into the wafer may be used as the recess for subsequent processing. In other method and package implementations, no particular reliance on using either the depth of the die streets or forming recesses may be used.

In various implementations, the plurality of recesses 6 may be formed with, by non-limiting example, a saw, a laser, a plasma etch, a chemical etch, or any other method for forming a recess in a wafer. In still other implementations, the sidewalls of the plurality of recesses 6 may be slightly patterned or ridged which may facilitate adhesion of a mold compound to the sidewalls of the plurality of recesses 6. In various implementations, the plurality of recesses 6 may be positioned in the wafer 2 so that they are between the semiconductor devices in the wafer. In other implementations, the plurality of recesses 6 may be positioned in the wafer so they are between the various semiconductor die formed in/on the wafer.

Still referring to FIG. 1, in various implementations, the method also includes applying a mold compound 10 to the first side 14 of the wafer 2. In particular implementations, the mold compound 10 encapsulates the plurality of electrical connectors 12 and fills the space of the plurality of recesses 6 thus coupling the mold compound 10 to the die 4. In various implementations, the mold compound may include, by non-limiting example, an epoxy, an acrylic, a resin, a filler, a pigment, a polymer, any combination thereof, or any other type of component of a material capable of filling the recesses. The mold compound may be applied using, by non-limiting example, a liquid dispensing technique, a transfer molding technique, a vacuum molding technique, a glob top molding technique, a compression molding technique, or any other mold compound application process. In other method implementations, however, no mold compound may be applied.

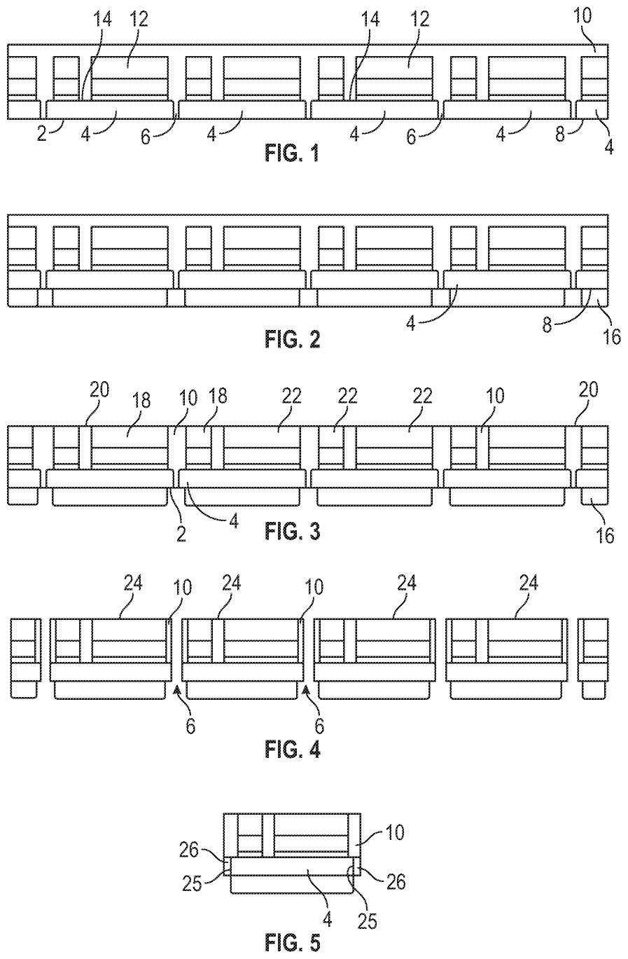

In various implementations, and as is illustrated by FIG. 1, the mold compound 10 may cover various sides/surfaces of the die. In particular implementations, the mold compound 10 may cover five sides of the three-dimensional die (the top surface and the four surfaces that extend across the thickness of the die for a die that is rectangular). In the implementation illustrated in FIG. 1, the entirety of the five sides of the die are covered by the mold compound 10. However, in other implementations the sides of the die 4 that extend across the thickness of the die may only partially be covered by a mold compound 10, while in still other implementations the mold compound 10 may not cover the sides of the die 4 that extend across the thickness at all. In various implementations, only a portion of a second side of the die may be covered by a mold compound. The mold compound covering the second side of the die 4 may be the same or a separate mold compound from the mold compound 10. In such implementations, the mold compound 10 may also cover the sides of a backside metal layer (16 in FIG. 2) in implementations where the backside metal layer is included and is the same length as or shorter than the length of the die 4.

Still referring to FIG. 1, a second side 8 of the wafer 2 is thinned to the desired depth of the plurality of recesses 6. In various implementations, the thinned wafer 2, or plurality of die 4, may be less than about 50 um thick, while in other implementations the thinned wafer, or plurality of die, may be more than about 50 or more um thick. In some implementations the thinned wafer 2 may be less than about 25 um thick, less than about 10 um thick, less than about 5 um thick, or less than about 1 um thick. The mold compound 10 coupled to the first side 14 of the wafer 2 and within the plurality of recesses 6 may facilitate thinning the wafer 2 by providing structural support to the wafer during the thinning process. The thinning process may be accomplished using various method, such as, by non-limiting example, backgrinding, lapping, polishing, grinding, etching, or any other method or process for thinning a semiconductor substrate material. In other implementations, the second side 8 of the wafer may not be thinned to the depth of the desired recesses 6. In this manner, the sides of the semiconductor die of each semiconductor package may take on a stepped shape upon final singulation of the wafer 2.

In various implementations, the semiconductor packages disclosed herein may include power semiconductor devices, however, in other implementations other semiconductor device types (transistors, microprocessors, passive components, etc.) may be utilized in the semiconductor packages. In various implementations, the semiconductor package includes one or more die. The die may be a silicon die, and in such implementations, the silicon die could be any type of silicon die including, by non-limiting example, an epitaxial silicon die, silicon-on-insulator, polysilicon, silicon carbide, any combination thereof, or any other silicon-containing die material. Further, it is also understood that in various implementations a die other than a silicon-containing die may be used, such as, by non-limiting example, gallium arsenide, ruby, sapphire, a metal-containing die, or any other semiconductor die type.

Referring to FIG. 2, a cross-sectional side view of the semiconductor package including a backside metal layer coupled to a second side of the wafer is illustrated. The method of forming the package that includes a backmetal may also include coupling a backside metal layer 16 to the second side 8 of the wafer. In various implementations, the backside metal layer (backmetal) 16 may be coupled over the semiconductor die 4. However, in various implementations, the backmetal layer may not be included at all, and so the process of coupling the backmetal may be dispensed with. In various implementations, the backside metal layer 16 may be a thick backside metal layer and in particular implementations, may be as thick as or thicker than the thickness of the thinned wafer. In various implementations, the backside metal layer 16 may be, by non-limiting example, copper, aluminum, tin, silver, gold, titanium, nickel, any combination thereof, any combination of layers thereof, or any other metal or metal alloy. It is also understood that any other electrically and/or thermally conductive material, including any metal or metal alloy disclosed herein, may be used.

In particular implementations, the backside metal layer may include, by non-limiting example, Ti/Ni/Cu, Ti/Cu, TiW/Cu, or any other type of metal stack or metal alloy including copper. In various implementations, and as illustrated by FIG. 2, the length of the backside metal layer 16 may be less than the length of the die 4. In such implementations, the die 4 may overhang the backside metal layer 16. In other implementations, the length of the backmetal layer 16 may be substantially the same as the length of the die 4 with the sides of the backmetal layer coextensive with the sides/perimeter of the die. In still other implementations, the back metal layer may extend beyond the sides/perimeter of the die 4. In various implementations, the back metal layer may be patterned.

In implementations where a back metal layer is employed (and also in implementations where it is not used), a stress relief etch may be utilized in various method implementations. This stress relief etch may be carried out after backgrinding and with or without back metal. In some implementations, the stress relief wet etching may take place after protecting the front side (die side) of the semiconductor substrate. The stress relief etching may reduce the backside damage to the semiconductor substrate that is caused by the backgrinding process. The use of the stress relief etching may also facilitate adhesion of any back metal applied to the ground surface. While the use of wet etching has been disclosed, in various implementations the use of dry etching could be employed in various implementations.

Referring to FIG. 3, a cross-sectional side view of the semiconductor package after the mold compound has been ground is illustrated. The method for forming the semiconductor package may include exposing an outer surface 18 of a plurality of bumps 22 through the mold compound 10 by grinding the mold compound 10. In various implementations, only the mold compound may be ground until it is coextensive with the surface 18, however, in other implementations the mold compound and a portion of the plurality of bumps 22 may be ground together. In this manner, the method may include planarizing the outer surface 18 of the plurality of bumps 22 with the outer surface 20 of the mold compound 10. The backmetal layer 16 may facilitate the thinning of the mold compound 10 by adding structural support to the wafer 2 and the plurality of die 4. In various implementations, the second side of the wafer may be thinned before the mold compound is ground to expose the plurality of bumps, however, in other implementations the method may include grinding the mold compound to expose the plurality of bumps before the second side of the wafer is thinned.

Referring to FIG. 4, a cross-sectional side view of the wafer after singulation into plurality of die is illustrated. The method for forming the semiconductor package includes singulating the mold compound 10 through the plurality of recesses 6 into a plurality of semiconductor packages 24. The mold compound may be singulated using, by non-limiting example, a saw, a laser, a plasma etch, water jet cutting, a chemical etch, or any other method for cutting or removing mold compound. In various implementations, the singulation line (or the width of the cut/etch made to singulate the mold compound) may be less wide as compared to the width of each recess of the plurality of recesses 6. In such implementations, the sidewalls of each die of the plurality of semiconductor packages may be at least partially covered by the mold compound 10. In implementations where the backside metal is not patterned, the backside metal may be singulated along with the mold compound to form the plurality of semiconductor packages. In various implementations, each of the plurality of die, or semiconductor packages, is separated through, by non-limiting example, stealth dicing, sawing, etching, laser ablating, laser damaging, scribing and breaking, or scribing and tape expanding.

Referring to FIG. 5, a cross-sectional side view of a single die with a passivating material on the die sidewalls is illustrated. As illustrated, the singulated semiconductor package includes mold compound 10. In addition, as illustrated, the semiconductor package includes a die 4 and in this implementation an oxide 26 of a predetermined thickness is deposited on at least a portion of one singulated surface/sidewall 25 of the die 4. In various implementations, the die 4 has a first largest planar surface and a second largest planar surface. In such implementations, the die has a thickness defined or formed by the space between the first largest planar surface and the second largest planar surface. In such implementations, the oxide 26 of a predetermined thickness is coupled at the thickness. In other various implementations, the method of forming the semiconductor package includes separating each of a plurality of die from each other at a plurality of junctions between each of the plurality of die, where each of the plurality of die forms a thickness. The oxide layer 26 of a predetermined thickness is then formed over a majority of the thickness of the die 4. In other various implementations, there may be more than one layer of oxide grown or deposited onto the surface of the die.

In particular implementations, forming the oxide includes using chemical vapor deposition. In various implementations, the oxide may be, by non-limiting example silicon dioxide, borophosphosilicate glass (BPSG), or another oxide of a semiconductive element or oxide of the material of the semiconductor die itself. The die 4 may have a perimeter that forms, by non-limiting example, a rectangular shape, an elliptical shape, a triangular shape, a polygonal shape, or any other closed shape. In other implementations, a method of growing the oxide 26 may include masking to prevent growth of the oxide layer on a largest planar surface of the die 4, or each of a plurality of die. In such implementations, the masking may include forming a patterned photoresist layer on the largest planar surface of the die, or each of the plurality of die to prevent deposition of oxide on the largest planar surface of the die and just on the thickness of the die. In still other implementations, the method may include overmolding the die, or each of the plurality of die, with a mold compound.

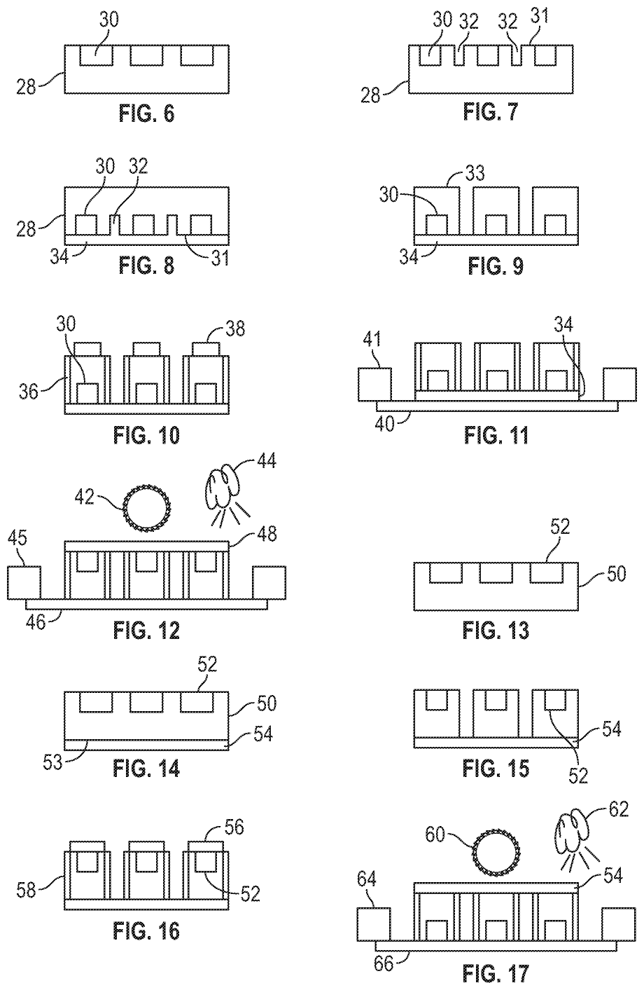

FIGS. 6-11 illustrate a plurality of die at various steps of a first implementation of a method of growing a passivating material (in this case an oxide) on sidewalls of semiconductor die where the wafer is notched or grooved first. Referring to FIG. 6, a cross-sectional side view of a wafer including semiconductor die is illustrated. As illustrated, a wafer 28 includes one or more semiconductor die 30 therein or thereon. Referring to FIG. 7, a cross-sectional side view of the wafer 28 including notches 32 formed in a first side 31 of the wafer 28 is illustrated. As illustrated, notches 32 are formed in a first side 31 of the wafer 28, in between the one or more semiconductor die 30. Referring to FIG. 8, a cross-sectional side view of the wafer after overmolding is illustrated. As illustrated, the wafer 28 is flipped so that the first side 31 is on the bottom (relative to bottom of the page). The notches 32 and the semiconductor die 30 are then overmolded with a mold compound 34, filling the notches 32, as illustrated. Referring to FIG. 9, a cross-sectional side view of the wafer after sawing is illustrated. As illustrated, the wafer is then background or sawed so that each semiconductor package 33, which includes a die 30, are separated, and remain still coupled with the mold compound 34.

Referring to FIG. 10, a cross-sectional side view of the semiconductor die with oxide on the die sidewalls is illustrated following growth of an oxide 36 is over at least a portion of the sidewalls of each die 30. The oxide layer 36 is of a predetermined thickness and in the implementation illustrated in FIG. 10 is formed over the entire thickness of the die 30. In various implementations, there may be more than one layer of oxide grown or deposited onto the surface of the die. In particular implementations, forming the oxide includes using chemical vapor deposition. In various implementations, the oxide may be any disclosed in this document. In various method implementations implementations, the die 4 has a perimeter that forms any of the various shapes disclosed in this document. In other implementations, a method of growing the oxide 26 may include masking to prevent growth of the oxide layer on a largest planar surface of the die 4, or each of a plurality of die. In such implementations, the masking may also include forming a patterned photoresist layer 38 on the largest planar surface of the die, or each of the plurality of die. In still other implementations, the method may include overmolding the die, or each of the plurality of die, with a mold compound.

Referring to FIG. 11, a cross-sectional side view of the semiconductor die coupled to a support is illustrated. As illustrated, the wafer and mold compound 34 is then coupled to a tape 40 which is coupled to a carrier or support 41. In various implementations, the support may be, by non-limiting example, a tape, a dicing tape, a, edge ring, another edge support, a carrier substrate, a carrier wafer, or any other support capable of supporting the die during subsequent operations. Referring to FIG. 12, an alternative cross-sectional side view of the semiconductor die couple to a support is illustrated. Instead of coupling the surface of the mold compound to the tape, the wafer may be flipped at the time it is mounted or coupled to the support 45 so that the mold compound 48 is not coupled to the tape 46, but the die-side of the wafer is, as illustrated. The wafer may then be singulated using, by non-limiting example, a sawing 42 technique, a plasma etch 44, a chemical etch, a laser scribing process, water jet ablation, or any other singulation technique.

FIGS. 13-17 illustrate a plurality of die at various steps in a second implementation of a method of growing a passivating material (in this case, an oxide) on sidewalls of semiconductor die where the plurality of die of the wafer is singulated first. Referring to FIG. 13, an alternative cross-sectional side view of a wafer including semiconductor die is illustrated. As illustrated, a wafer 50 includes one or more semiconductor die 52. Referring to FIG. 14, a cross-sectional side view of the wafer after overmolding on the backside of the wafer is completed is illustrated. As illustrated, the wafer 50, which includes the one or more semiconductor die 52 is overmolded with a mold compound 54 on a backside 53 of the wafer 50. Referring to FIG. 15, a cross-sectional side view of the wafer after singulation through to the mold compound is illustrated. The singulation may be carried out using any singulation method disclosed in this document. As illustrated, the wafer with semiconductor die 52 is then singulated through to the mold compound 54 using any singulation technique disclosed in this document.

Referring to FIG. 16, a cross-sectional side view of the plurality of die with oxide formed on the die sidewalls is illustrated. As illustrated, the oxide layer 58 of a predetermined thickness is then formed over the sidewalls or thickness of each of the die 52. In other various method and package implementations disclosed herein, there may be more than one layer of oxide grown or deposited onto the surface of the die and the layers may be of different oxide types. In various implementations, forming the oxide may include forming using any method and any oxide material disclosed herein. In various implementations, the die 52 has a perimeter that has any shape disclosed herein. As previously discussed, in this method implementation growing the oxide 58 may include masking to prevent growth of the oxide layer on a largest planar surface of the die 52, or each of a plurality of die. In such implementations, the masking be a patterned photoresist layer 56 formed on the largest planar surface of the die, or each of the plurality of die to prevent growth of the oxide on the surface. In still other implementations, the method may include overmolding the die, or each of the plurality of die, with a mold compound.

Referring to FIG. 17, a cross-sectional side view of the semiconductor die coupled to a tape is illustrated. As illustrated, the wafer and mold compound 54 is mounted/coupled to a tape 66 which is coupled to a frame/carrier/support 64. As illustrated, the wafer may be flipped so that the mold compound 54 is not coupled to the tape 66, as illustrated. The wafer may then be singulated using a sawing 60 technique as illustrated, a chemical etch 62, or any other singulation technique disclosed herein.

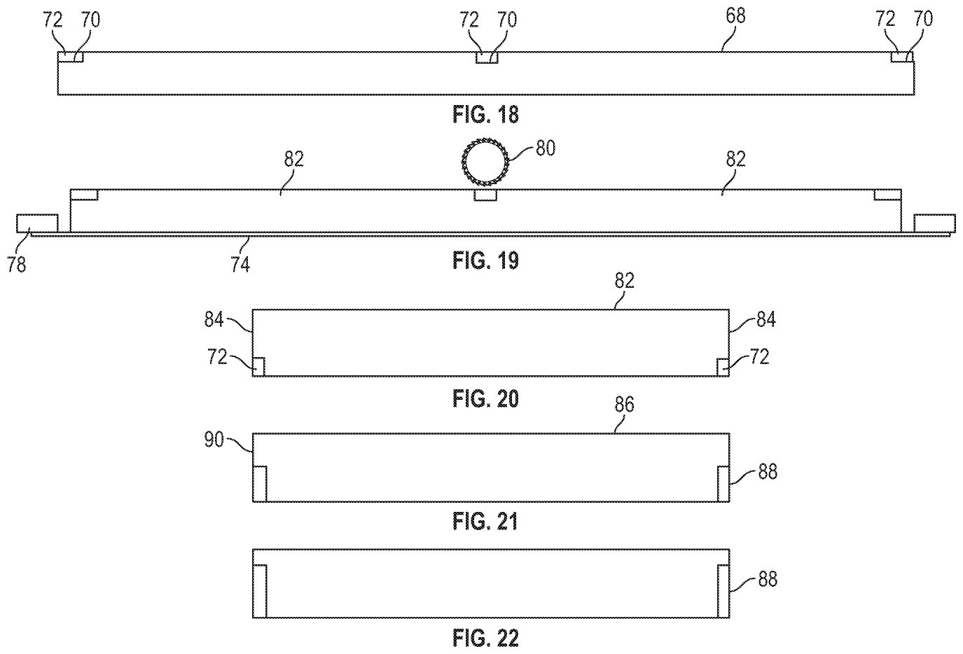

Referring to FIG. 18, an implementation of a semiconductor substrate 68 is illustrated. In this implementation, the substrate has been grooved a certain distance into the material of the substrate to form a plurality of grooves 70. In various implementations, the grooving may be conducted after the frontside metallization of the semiconductor die of the semiconductor substrate is finalized. In some implementations, the grooving may be conducted after the frontside metallization is formed but either before or after frontside solderable metallization is added. In various method implementations, this grooving may be done using, by non-limiting example, a saw pre-cut process, a laser ablation process, a plasma etching process, a wet chemical etching process, or any other process for forming a groove in the material of a semiconductor substrate. The semiconductor substrate may be any disclosed in this document. Into the plurality of grooves a passivating material (in this case oxide 72) has been formed/deposited which may be any type of oxide disclosed in this document.

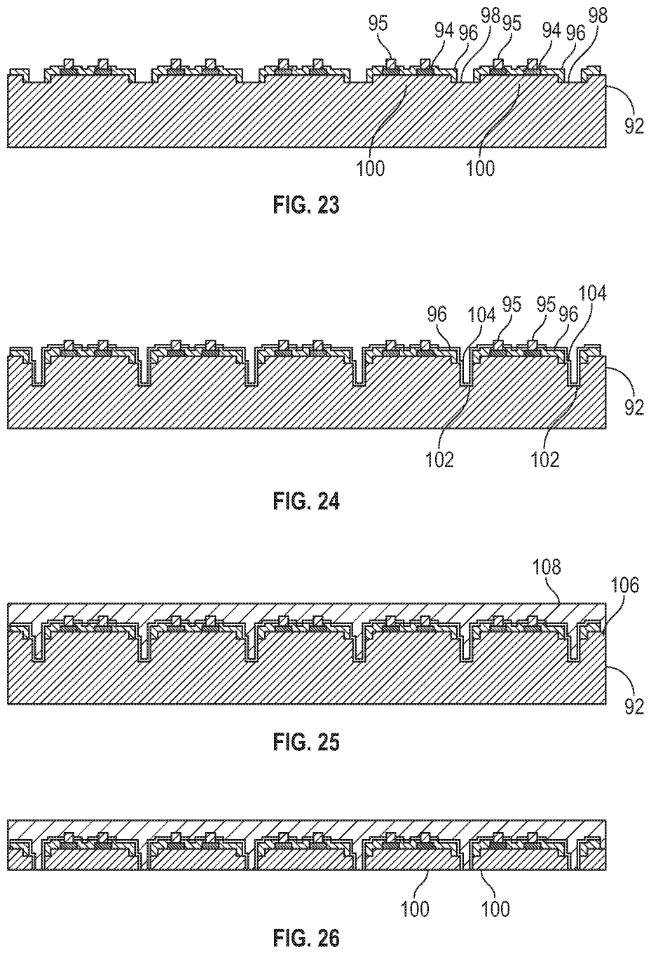

Referring to FIG. 19, the substrate 68 of FIG. 18 is illustrated after mounting to a dicing tape 74 and frame 78 just prior to singulation using saw blade 80. As illustrated, the saw blade 80 is positioned to cut through the oxide and then into the material of the semiconductor substrate 68 to singulate each die 82 in the semiconductor substrate. FIG. 20 illustrates a singulated semiconductor die 82 that indicates that the oxide 72 extends about one quarter of the way along the singulated surface 84 of the die 82. FIG. 21 illustrates a die 86 that has oxide 88 that extends about half way along the singulated surface/sidewall 90 of the die 86. FIG. 22 illustrated a die 92 that has oxide 94 that extends about half way along the singulated surface 96 of the die 92. The length the oxide extends along the singulated surface of the die can be determined in two ways, either alone or combination. In the first method, the depth of the plurality of grooves into the semiconductor substrate can be adjusted to be deeper or shallower into the material of substrate. In the second method, the semiconductor substrate can be background/thinned to different thicknesses, which will determine the distance the oxide will extend along the singulated surface of the die. Both methods may be employed in various implementations to create the desired oxide coverage on the singulated surface die. A wide variety of possible method implementations and oxide configurations are possible using the principles disclosed in this document.

Referring to FIGS. 23-26 a semiconductor substrate 92 is illustrated at various steps in an implementation of a method of forming a semiconductor package with passivating materials along the singulated sides of a plurality of die is illustrated. In FIG. 23, the substrate 92 is illustrated after formation of the semiconductor devices and the formation of the initial frontside metallization that includes pads 94 and passivation material 96. Contacts 95 are also illustrated that are coupled to pads 94. As illustrated, die streets 98 separate each semiconductor die 100 and extend a certain distance into the substrate 92 as a result of processing during die fabrication. FIG. 24 illustrates the substrate 92 following grooving of the die streets 98 to form grooves 102 into the substrate material 92. Passivating material 104 is then deposited over the grooves and existing passivation material 96 except for the contacts 95. This may be accomplished through a masking process like any disclosed herein. The passivating material 104 in this case in any of a wide variety of die passivating materials such as, by non-limiting example, silicon nitride, borophosphosilicate glass (BPSG), silicon dioxide, spin-on-glass (SOG), any oxide disclosed herein, any combination thereof, or any other die passivation material. FIG. 25 illustrates the substrate 92 following application of an organic material 108 over the first side 106 of the substrate 92 and into the grooves 102. Following the application of the organic material 108, FIG. 26 illustrates the substrate 92 following backgrinding/thinning that serves to physically singulate the plurality of die 100. The organic material 108 can then be leveled/ground as disclosed in this document to expose the contacts 95 and the resulting plurality of semiconductor packages can then be singulated using any of the methods disclosed herein.

In this method implementation, while the final singulation of each of the die from each other die is accomplished after backgrinding, the singulated surface of the die is formed at the grooving step, and thus the passivating material 104 covers the entire singulated/cut surface of the die or a majority of the singulated/cut surface of the die. In this way, this method implementation contrasts with that one illustrated in FIGS. 18-22 where the die singulation is accomplished at least partly through cutting through the oxide applied into the grooves. In this implementation, the singulation/cutting step is completed before the passivating material 104 is deposited/applied to the singulated surfaces of the die. In this method implementation, backmetal may also be formed prior to singulation, whether patterned or unpatterned using any method or process disclosed in this document.

In various method implementations, a stress relief wet etching process may be carried out following thinning of the substrate. In such implementations, the stress relief wet etching may be carried out with or without backmetal. In some implementations, the stress relief wet etching may take place after protecting the front side (die side) of the semiconductor substrate. The stress relief etching may reduce the backside damage to the semiconductor substrate that is caused by the backgrinding process. The use of the stress relief etching may also facilitate adhesion of the backmetal applied to the ground surface. In various implementations, the application of the temporary or permanent die support structures may be carried out prior to a backmetal formation process.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor packages.

What is claimed is:

1. A semiconductor package comprising:
a singulated die; and
a passivating material of a predetermined thickness across a majority of a singulated surface of the singulated die on at least one singulated surface of the singulated die.

2. The semiconductor package of claim 1, wherein the singulated die comprises a perimeter comprising a closed shape.

3. The semiconductor package of claim 1, wherein the singulated die comprises a perimeter comprising a rectangular shape.

4. The semiconductor package of claim 1, wherein the singulated die comprises a perimeter comprising an elliptical shape.

5. The semiconductor package of claim 1, wherein the singulated die comprises a perimeter comprising a triangular shape.

6. The semiconductor package of claim 1, wherein the singulated die comprises a perimeter comprising a polygonal shape.

7. The semiconductor package of claim 1, wherein the passivating material comprises one of silicon dioxide and borophosphosilicate glass (BPSG).

8. A semiconductor package comprising:
a die having a first largest planar surface and a second largest planar surface, the die comprising a thickness between the first largest planar surface and the second largest planar surface, the thickness including a cut surface; and
a passivating material of a predetermined thickness coupled at the thickness and extending along at least half of the cut surface of the thickness to the second largest planar surface.

9. The semiconductor package of claim 8, wherein the die comprises a perimeter comprising a closed shape.

10. The semiconductor package of claim 8, wherein the die comprises a perimeter comprising a rectangular shape.

11. The semiconductor package of claim 8, wherein the die comprises a perimeter comprising an elliptical shape.

12. The semiconductor package of claim 8, wherein the die comprises a perimeter comprising a triangular shape.

13. The semiconductor package of claim 8, wherein the die comprises a perimeter comprising a polygonal shape.

14. The semiconductor package of claim 8, wherein the passivating material comprises one of silicon dioxide and borophosphosilicate glass (BPSG).

15. A method of singulating a die comprising:
at least partially separating each of a plurality of die from each other at a plurality of junctions between each of the plurality of die, each of the plurality of die comprising a thickness comprising a cut surface; and
forming a passivating material of a predetermined thickness across at least a portion of the cut surface of the thickness.

16. The method of claim 15, wherein forming the passivating material further comprises using chemical vapor deposition.

17. The method of claim 15, wherein each of the plurality of die is separated through one of stealth dicing, sawing, etching, laser ablating, laser damaging, scribing and breaking, or scribing and expanding.

18. The method of claim 15, further comprising masking to prevent growth of the passivating material on a largest planar surface of each of the plurality of die.

19. The method of claim 18, wherein the masking comprises forming a photoresist layer on the largest planar surface of each of the plurality of die.

20. The method of claim 15, further comprising overmolding each of the plurality of die with a mold compound.
